(19) United States
(12) Patent Application Publication
(10) Pub. No.: US 2010/0000860 A1
(43) Pub. Date: Jan. 7, 2010

(54) Copper Sputtering Target With Fine Grain Size And High Electromigration Resistance And Methods Of Making the Same

(75) Inventors: Yongwen Yuan, Dublin, OH (US); Robert S. Bailey, Grove City, OH (US); Eugene Y. Ivanov, Grove City, OH (US); David B. Smathers, Columbus, OH (US)

Correspondence Address: WEGMAN, HESSLER & VANDERBURG, 6055 ROCKSIDE WOODS BOULEVARD, SUITE 200, CLEVELAND, OH, 44131, US

(73) Assignee: TOSOH SMD, INC., Grove City, OH (US)

(21) Appl. No.: 12/310,699

(22) PCT Filed: Aug. 29, 2007
(86) PCT No.: PCT/US2007/018977

§ 371 Date: Mar. 24, 2009

Related U.S. Application Data
(60) Provisional application No. 60/843,075, filed on Sep. 8, 2006.

(51) Int. Cl. C22C 9/00; C23C 14/34; B22D 23/00; C22F 1/08; C22C 9/01

(52) U.S. Cl. 204/298.13; 164/47; 164/76.1; 148/554; 148/432; 148/436; 420/469; 420/489

(57) ABSTRACT

The present invention generally provides a sputtering target comprising copper and a total of 0.001 wt %˜10 wt % alloying element or elements chosen from the group consisting of Al, Ag, Co, Cr, Ir, Fe, Mo, Ti, Pd, Ru, Ta, Sc, Hf, Zr, V, Nb, Y, and rare earth metals. An exemplary copper sputtering containing 0.5 wt % aluminum has superfine grain size, high thermal stability, and high electromigration resistance, and is able to form films with desired film uniformity, excellent resistance to electromigration and oxidation, and high adhesion to dielectric interlayer. An exemplary copper sputtering containing 12 ppm silver has superfine grain size. This invention also provides methods of manufacturing copper sputtering targets.

### CROSS-REFERENCE TO RELATED APPLICATION

This application claims the priority benefit of U.S. Provisional Patent Application Ser. No. 60/843,075 filed Sep. 8, 2006.

### FIELD OF THE INVENTION

The present invention relates generally to the physical vapor deposition of metal films and more specifically to copper sputtering targets with reduced grain size and improved film performance.

### BACKGROUND OF THE INVENTION

Aluminum interconnects have been used to connect the devices in integrated circuits for decades. As the microelectronics industry drives the miniaturization of devices and circuits towards nanometer dimension, ever-increasing stringent demands have been placed on the metal interconnection network. Copper is becoming popular for replacing aluminum to form interconnects with substantially shrunken dimension for large-scale integrated circuits and flat panel display devices because it has many advantages over aluminum. Compared to aluminum, copper has lower electrical resistivity, higher thermal conductivity, and higher melting point and electromigration resistance.

However, there are several issues associated with copper interconnects. Firstly, even though in principle the electromigration resistance of copper is several orders of magnitude larger than that of aluminum, this resistance can be significantly degraded by the abnormal grain growth or low thermal stability of pure copper. Significant grain growth has been observed at temperatures starting at 250° C. and below 400° C. for pure copper. Secondly, copper has poor corrosion resistance and cannot form a good self-passivating layer barrier like the dense and stable aluminum oxide (Al₂O₃). Thirdly, copper has poor adhesion to surrounding dielectric interlayers such as silicon dioxide (SiO₂) and could readily diffuse into the dielectric layers.

In absence of chemical bonding at the interface, the standard practice of achieving desired adhesion is to deposit an interfacial bonding layer between the two materials of interest. Ideally, this layer not only promotes the formation of chemical bonding at the interface but also acts as a diffusion barrier preventing unwanted interaction between the two materials, i.e., the interfacial layer works as adhesion promoter and diffusion barrier (APDB). A tantalum (Ta)-tantalum nitride (TaN) layer has been found to be an APDB for copper interconnect. However, the effectiveness of the Ta—TaN APDB layer is limited by its relatively large thickness (>10 nm) and high as-processed resistivity (>100 μΩ) when the minimum feature size in the silicon semiconductor moves below 180 nanometers. All these issues need to be addressed to promote the widespread use of copper in the place of aluminum in microelectronics industry.

Metal interconnects are patterned from the films commonly deposited by a sputtering process. Major sputtering system components include the sputtering target, sputtering chamber, power supply, and vacuum system. An exemplary sputtering system 100 is described in FIG. 1 to illustrate exemplary film formation process. System 100 is an example of sputtering apparatus which comprises a vacuum chamber 122 with sidewalls 123. A sputtering target 10 described in FIG. 2 locates the upper side of the chamber. The target 10 is surrounded by shield 124. A substrate 128 locates at the bottom side of the chamber. During the sputtering process, a plasma 120 is formed between the target and substrate. The target surface 11 is bombarded with energetic charged particles 125 accelerated by high voltage (a large negative voltage was applied on the target by the power supplier 130), which causes the ejection of surface atoms 126. The ejected atoms are transported and condensed on the substrate 128 as a metal film 129 of the target composition. The deposited film 129 is further patterned to form interconnects (not shown) for interconnecting the devices fabricated on the substrate. The sputtering target is the key component for the sputtering deposition of metal films whose performance is determined by the material characteristics of the sputtering target.

Target grain size directly affects sputtering rate and film uniformity. It is believed that the atoms at the grain boundaries of the target material are more easily bombarded and ejected to form film on the substrate because of their weaker bonding force compared to the interior atoms of crystal lattices. The film uniformity has been found to be correlated to the grain size. In general, the finer the grain size, the better the film uniformity.

### SUMMARY OF THE INVENTION

The present inventors have discovered a sputtering target comprising copper and a total of 0.001 wt %˜10 wt % of one or more of other elements including Al, Ag, Co, Cr, Ir, Fe, Mo, Ti, Pd, Ru, Ta, Sc, Hf, Zr, V, Nb, Y, and rare earth metals, and have provided manufacturing methods for such a copper sputtering target.

The present invention provides a method to improve the performance of the films formed from the copper sputtering targets. Doping copper with Al, Ag, Co, Cr, Ir, Fe, Mo, Ti, Pd, Ru, Ta, Sc, Hf, Zr, V, Nb, Y, and rare earth metals increases the thermal stability and electromigration resistance of the copper. Doping copper with aluminum and iridium forms an oxide layer to prevent copper from further oxidation and forms a layer of adhesion promoter-diffusion barrier to improve the adhesion capability of copper to surrounding dielectric materials.

The grain size of the sputtering target has significant impact on the sputtering process, properties and the performance of the deposited films. Our alloyed copper target has average grain size of less than 10 microns, which is smaller than the typical reported grain size of 25˜50 microns of conventional copper targets. In addition, alloyed copper target has enhanced thermal stability and electromigration resistance compared to a pure copper.

In one exemplary embodiment, the present invention provides a copper sputtering target containing 0.5 wt % aluminum (referred to as Cu 0.5 wt % Al). The Cu 0.5 wt % Al sputtering target possesses a superfine grain size of 10 micrometer, significantly increased recrystallization temperature and thermal stability, and enhanced electromigration resistance compared to a pure copper target. The Cu 0.5 wt % Al sputtering target can form metal films and interconnects having desired film uniformity, high resistance to electromigration and oxidation, and strong adhesion to dielectric interlayer.

### BRIEF DESCRIPTION OF THE DRAWINGS

The following description makes reference to the accompanying drawings, in which:

FIG. 1 is a schematic diagram of an exemplary sputtering system.

FIG. 2 is a schematic cross-sectional view of an exemplary Forte® bonded copper target construction of the present invention.

FIG. 3 is a plot of hardness as a function of recrystallization annealing temperature for the Cu 0.5 wt % Al target materials. The anneal time is fixed at 1 hour.

FIG. 4 is a plot of conductivity as a function of recrystallization anneal temperature for the Cu 0.5 wt % Al target materials. The anneal time is fixed at 1 hour.

FIG. 5 is the microstructure evolution of Cu 0.5 wt % Al target material with increasing recrystallization anneal temperatures.

FIG. 6 is normal and transverse view metallographs and grain sizes at different locations of the Cu 0.5 wt % Al target materials annealed at 400° C. for 2 hours.

### DETAILED DESCRIPTION OF THE PREFERRED EMBODIMENTS

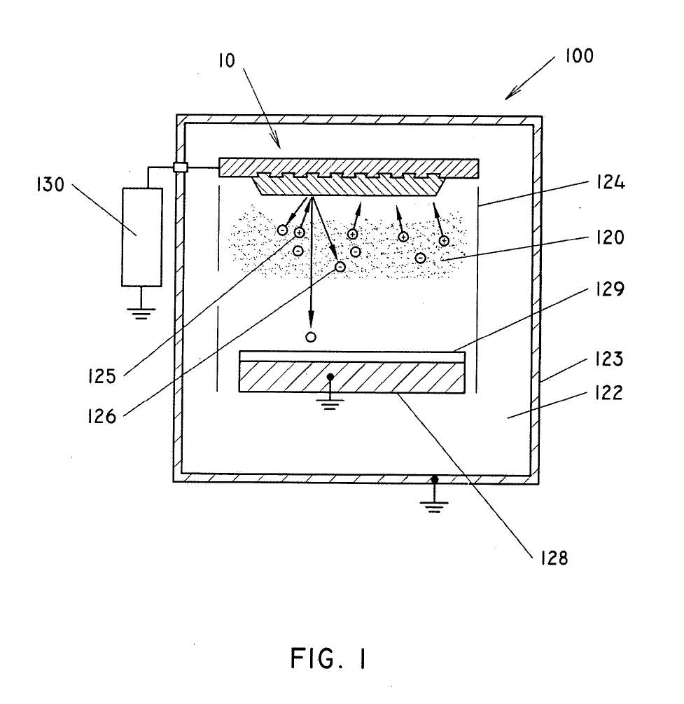

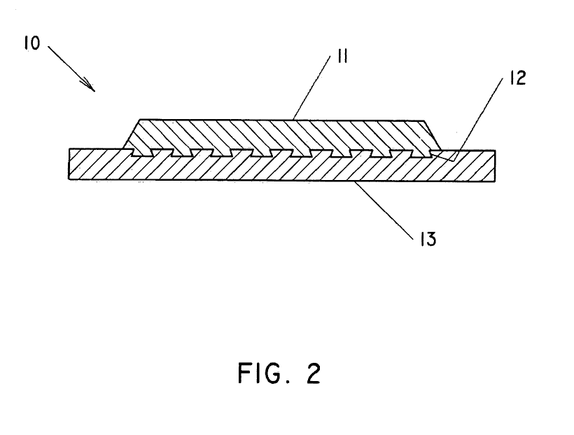

The copper sputtering target encompassed by this invention can have any suitable geometry, and can be bonded to the backing plate 13 or monolithic. The bond 12 can be either solder bond or Tosoh SMD patented Forte® bond as set forth in U.S. Pat. No. 6,749,103, incorporated by reference herein. The target encompassed by this invention can be applied in any suitable sputtering apparatus including, but not limited to the apparatus with reference to FIG. 1.

The present invention includes methods of manufacturing the copper target containing one or more of other alloying elements including Al, Ag, Co, Cr, Ir, Fe, Mo, Ti, Pd, Ru, Ta, Sc, Hf, Zr, V, Nb, Y, and rare earth metals. The copper raw material will preferably have a purity of at least 99.9995 wt %. The alloying elements may have lower purity, for example, the iridium raw material will preferably have a purity of 99.5 wt %. The titanium raw material will preferably have a purity of 99.995 wt %. The palladium raw material will preferably have a purity of 99.95 wt %. The tantalum will preferably have a purity of at least 99.5 wt %. The rare earth metals will preferably have a purity of at least 99 wt %.

The copper and one or more of other elements including Al, Ag, Co, Cr, Ir, Fe, Mo, Ti, Pd, Ru, Ta, Sc, Hf, Zr, V, Nb, Y, and rare earth metals are melted to form a molten alloy preferably through a vacuum induction melting process. The molten alloy is subsequently cooled and cast to form an alloy ingot of copper and one or more of other elements at the levels of from 0.001 wt % up to 10 wt %.

An example of this kind of alloy is copper and 0.5 wt % aluminum. Its composition results measured by standard analytical techniques ICP, GDMS, and LECO are listed in the TABLE 1. (The weight concentration unit is ppm for all elements except aluminum Al whose unit is percent (%)). It should be understood that the aluminum content in the copper-aluminum alloy of the present invention can range from 0.001 wt % to 10 wt %. The resulting ingot can have any size and any suitable shapes including round, square, and rectangular.

The ingot of copper alloying with a small amount of one or more of other elements undergoes a thermomechanical process to form desired grain structure, especially desired fine grain size. The annealed plate or blank of copper alloy is machined into a target which is bonded to backing plate through solder bond or the aforementioned Tosoh SMD patented Forte® bond, or machined into a monolithic target.

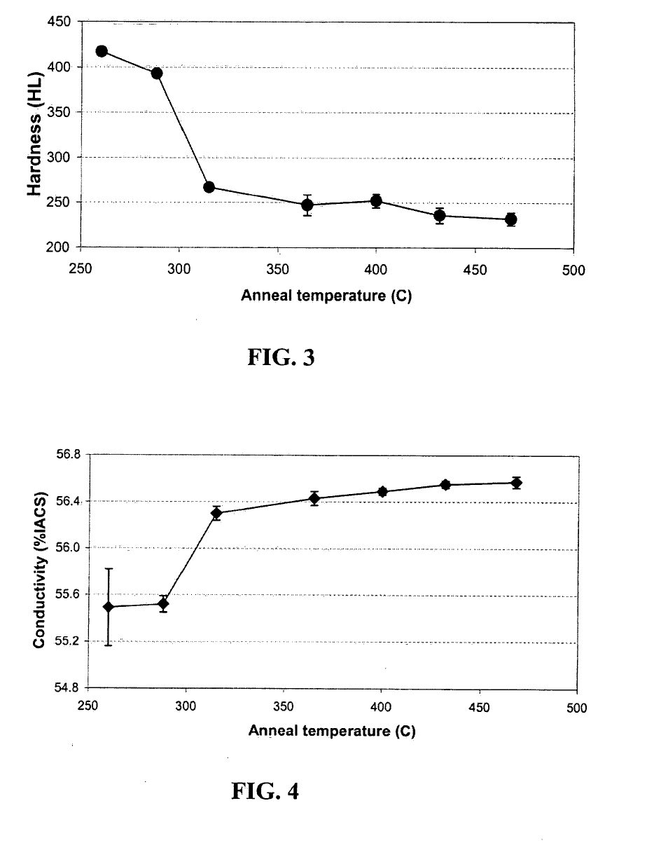

An exemplary thermomechanical process includes hot or cold press, hot and cold roll, hot and cold forge, extrusion, and anneals for an exemplary Cu 0.5 wt % Al copper alloy. The hot and cold rolls will preferably comprise cross-direction rolling steps. A plate or blank resulting from the mechanical deformation is subjected to recrystallization anneal process at the temperatures varied from 260° C. to 470° C. for 0.5˜4 hours. Leeb's hardness and electrical conductivity are measured for the annealed exemplary Cu 0.5 wt % Al target blanks. FIG. 3 and FIG. 4 plot the hardness and electrical conductivity as a function of recrystallization anneal temperature. The hardness decreases while electrical conductivity increases with increasing the anneal temperature.

The driving force for the recovery and recrystallization process is the internal energy stored in the deformed original grains. The material is softened and hardness decreases when the work-hardening stress is released by forming new strain-free grains in the recrystallization process. A considerable change in electrical resistance or its inverse, electrical conductivity typically occurs in the early stages of annealing as a consequence of the pre-recrystallization process (recovery) of localized defect rearrangement. With reference to FIG. 3 and FIG. 4, a conductivity jump and a hardness decrease suggests the recrystallization of Cu 0.5 wt % Al starts to take place around 315° C.

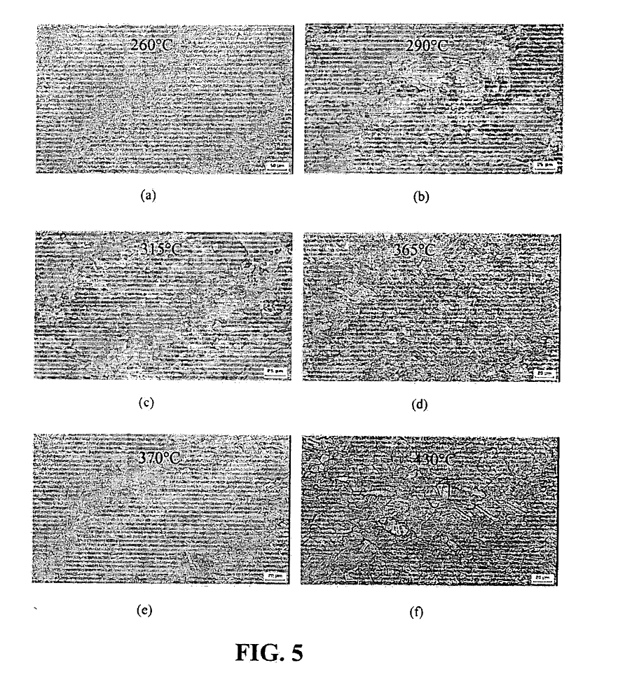

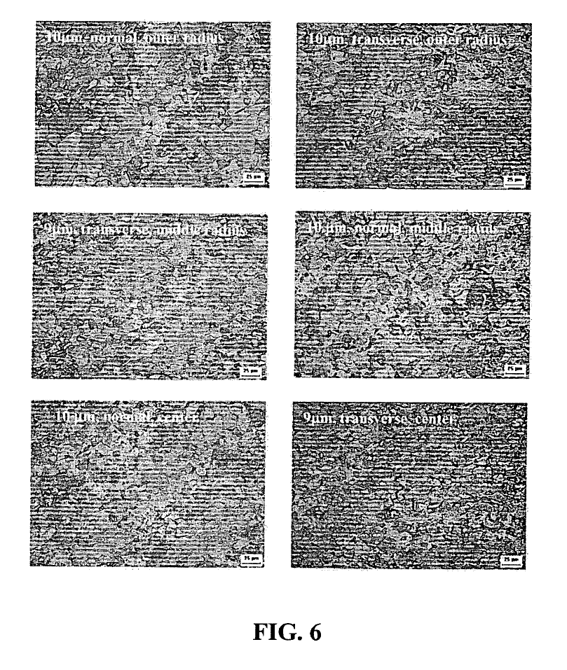

The microstructure evolution confirms that the recrystallization of deformed Cu 0.5 wt % Al starts around 315° C. and is complete at a temperature of 365° C. (FIG. 5d), which is substantially higher than the typical recrystallization temperature of 260° C. for the pure copper (5N or 6N) subjected to the same fabrication process. FIG. 6 are metallographs for the Cu 0.5 wt % Al target annealed at 400° C. for 2 hours. These illustrate that the annealed target has uniform and superfine grain size (the grain size is determined by the ASTM E112 Standard Test Method). Even though it is subjected to a recrystallization anneal of higher temperature (400° C.) and longer time (2 hours) than that of 260° C. and 1 hour usually for pure copper, its grain size of 9˜10 micrometer is smaller than the typical grain size of 15 micrometer for fully recrystallized pure copper target at 260° C. for 1 hour (typical grain size for commercial pure copper is about 30 micrometers).

TABLE 1

| Element | Value | Method Of Analysis |
|---|---|---|
| Al* | 0.5* | ICP |
| C | 10 | LECO |
| S | 10 | LECO |
| H | 0.4 | LECO |
| N | 10 | LECO |
| O | 3 | LECO |
| Li | 0.002 | GDMS |
| Be | 0.001 | GDMS |
| B | 0.005 | GDMS |
| F | 0.003 | GDMS |
| Na | 0.3 | GDMS |
| Mg | 0.011 | GDMS |
| Si | 0.062 | GDMS |
| P | 0.11 | GDMS |
| Cl | 0.024 | GDMS |
| K | 0.053 | GDMS |
| Ca | 0.02 | GDMS |
| Sc | 0.001 | GDMS |
| Ti | 0.047 | GDMS |
| V | 0.001 | GDMS |
| Cr | 0.021 | GDMS |
| Mn | 0.001 | GDMS |
| Fe | 0.02 | GDMS |
| Co | 0.009 | GDMS |
| Ni | 0.024 | GDMS |
| Zn | 0.028 | GDMS |
| Ga | 0.01 | GDMS |
| Ge | 0.006 | GDMS |
| As | 0.054 | GDMS |
| Se | 0.089 | GDMS |
| Br | 0.006 | GDMS |
| Rb | 0.001 | GDMS |
| Sr | 0.001 | GDMS |
| Y | 0.001 | GDMS |
| Zr | 0.002 | GDMS |
| Mo | 0.005 | GDMS |
| Nb | 0.001 | GDMS |
| Ru | 0.003 | GDMS |
| Pd | 0.003 | GDMS |
| Ag | 0.21 | GDMS |
| Cd | 0.01 | GDMS |
| In | 0.003 | GDMS |
| Sn | 0.33 | GDMS |
| Sb | 0.11 | GDMS |
| Te | 0.09 | GDMS |
| I | 0.002 | GDMS |
| Cs | 0.001 | GDMS |
| Ba | 0.001 | GDMS |
| La | 0.001 | GDMS |
| Ce | 0.001 | GDMS |
| Pr | 0.001 | GDMS |
| Nd | 0.002 | GDMS |
| Sm | 0.002 | GDMS |
| Eu | 0.001 | GDMS |
| Gd | 0.002 | GDMS |
| Tb | 0.001 | GDMS |
| Dy | 0.002 | GDMS |
| Ho | 0.001 | GDMS |
| Er | 0.003 | GDMS |
| Tm | 0.001 | GDMS |
| Yb | 0.003 | GDMS |
| Lu | 0.001 | GDMS |
| Hf | 0.007 | GDMS |
| W | 0.004 | GDMS |
| Re | 0.001 | GDMS |
| Os | 0.002 | GDMS |
| Ir | 0.001 | GDMS |
| Pt | 0.003 | GDMS |
| Au | 0.003 | GDMS |
| Hg | 0.03 | GDMS |
| Tl | 0.001 | GDMS |
| Pb | 0.005 | GDMS |
| Bi | 0.02 | GDMS |
| Th | 0.0002 | GDMS |
| U | 0.0002 | GDMS |

Furthermore, the deformed Cu 0.5 wt % Al can still attain a grain size˜10 micrometer after being annealed at temperatures as high as 500° C. In contrast, significant grain growth is seen in pure copper annealed at 400° C. (the change in pure Cu films happens at 250° C. to 350° C.) which leads to the roughening of copper films deposited from the target and causes serious problems for multilevel metallization.

We have found that copper alloying with some other metallic elements such as aluminum can result in ultra fine and uniform grain size equal to or less than 10 micrometer and significant improvement in thermal stability. Lower thermal stability or abnormal growth in the deposited film is one of the major concerns associated with the utilization of pure copper sputtering target in forming interconnects. Low thermal stability or abnormal growth is characterized by a tendency of the individual crystal grains to grow when exposed to certain temperature. The higher the recrystallization or grain growth temperature, the higher the thermal stability. High thermal stability or low abnormal growth enhances the electromigration resistance of the deposited film. Similar improvement in grain size refining, thermal stability, and electromigration resistance can be attained in the copper by alloying with one or more of other elements including Al, Ag, Co, Cr, Ir, Fe, Mo, Ti, Pd, Ru, Ta, Sc, Hf, Zr, V, Nb, Y, and rare earth metals. Alloying copper with other elements provides an approach to effectively reduce grain size and enhance thermal stability and electromigration resistance.

The film deposited from the target of copper alloying with other elements such as aluminum has an enhanced oxidation resistance. The aluminum in the film formed from an exemplary target of Cu 0.5 wt % Al can inhibit the oxidation of copper in two ways. First, the presence of aluminum reduces the concentration of the vacancy which is believed to be necessary for the transport of copper ions through the already formed copper oxide layer to the surface where they are oxidized. The aluminum tends to occupy the vacancy sites in the copper crystal lattices and reduces the oxidation of copper. Additionally, aluminum atoms can diffuse to the copper surface and form an aluminum oxide thin layer (˜4 nanometer). This dense and stable oxide layer blocks the transport of either copper or oxygen and prevents the further oxidation of copper. In the case of copper alloying with titanium, the occupancy of titanium at copper vacancy sites and the formation of titanium oxides thin layers prevent the further oxidation of copper. Therefore, the film deposited from the copper targets alloying with aluminum and titanium in the present invention have a significantly improved corrosion/oxidation resistance than those from the films deposited from pure copper target, which is important for liquid crystal display thin film transistor applications.

Low resistivity is desired for interconnects applications. The resistivity of copper increases when copper is alloyed with other elements. FIG. 4 exemplifies that addition of 0.5 wt % Al in Cu causes a decrease in conductivity (100% ICAS for pure Cu). However, the aluminum in the film deposited from the target of copper alloying with a small amount of aluminum can be consumed by diffusing to the copper surface to form a passivating aluminum oxide thin layer after a post-deposition anneal. This solute purification can result in a low aluminum concentration in the bulk of the film and thus attains reasonably high electrical conductivity while maintaining high corrosion resistance.

The poor adhesion of copper to surrounding dielectric layers such as SiO₂ is another issue blocking widespread replacement of aluminum with copper in silicon semiconductor industry. An approach to solve this problem is to deposit an interfacial thin layer of Ta—TaN between SiO₂ and Cu layers to enhance the adhesion of copper to SiO₂. Another benefit of alloying copper with other elements like aluminum provides an alternative approach to improve the adhesion of copper to surrounding dielectric interlayer without depositing additional Ta—TaN liner layer. It is known aluminum is thermodynamically favorable to interact with SiO₂ leading to excellent adhesion to SiO₂ and good contact with silicon. The aluminum in the copper films deposited from the alloyed copper target can diffuse to the metal/SiO₂ interface and reduce the SiO₂ to form strong chemical bonds between copper and SiO₂ atomic layers. This can result in the elimination of Ta—TaN APDB layer and reduce the fabrication cost. On the other hand, the out-diffusion of the alloying element aluminum purifies the copper metal layer and leads to low resistivity in the bulk of metal layers.

It is apparent then, that in one aspect of the invention, a stable oxide layer is formed along the surface of the target and prevents further oxidation of the target. Targets in accordance with the invention may be utilized, as stated above, to form films/interconnects in microelectronic devices. Also, and as previously mentioned, the alloying elements present in the alloy may diffuse to the metal film/dielectric layer interface and reduce surrounding dielectric interlays to form interfacial chemical bonds and a diffusion barrier layer. The films/interconnects so formed possess enhanced adhesion to surrounding dielectric layers.

One aspect of the invention is directed toward a copper alloy sputter target comprising copper and aluminum alloying element present in an amount of 0.001 wt % to 10 wt %, more preferably 0.1-1 wt %, and most preferably about 0.5 wt %. These targets have uniform grain sizes throughout the target of 10 μm or less. Additionally, in this embodiment, from about 0.01-50 ppm of a second alloying element or elements may be present selected from the group of Ag, Co, Cr, Ir, Fe, Mo, Ti, Pd, Ru, Ta, Sc, Hf, Zr, V, Nb, Y, and rare earth metals. These targets exhibit a conductivity of between about 55.2-56.8% IACS. Further, the copper in such copper alloy target may, by itself, have purity level of at least 5 N.

After the requisite copper and alloying elements are mixed, cast, and cooled, they are subject to thermomechanical working steps comprising a hot or cold rolling, hot or cold pressing, forging, or extrusion and at least one annealing step. The annealing may be conducted at temperatures of between about 315° C. to 470° C.

It is apparent then that alloying copper with metallic elements as set forth above results in enhanced oxidation resistance and adhesion to dielectric interlayers of the deposited films. The refined grain size can result in higher sputtering rate and better film uniformity. The improved thermal stability, electromigration resistance, oxidation resistance, and adhesion ability to dielectric interlayers can enhance the performance of the deposited films used in large scale integrated circuits and flat panel display devices.

The present invention has been disclosed in connection with the preferred embodiments thereof, it should be understood that the invention is not limited to the specific embodiments described since the means herein comprise preferred forms of putting the invention into effect, and other embodiments may be within the scope of the invention as defined by the following claims.

What the invention claimed is:

1. A copper alloy sputter target comprising Cu and from about 0.001 wt %-10 wt % of one or more alloying elements.

2. A copper alloying sputter target as recited in claim 1 wherein said one or more alloying elements are selected from the group consisting of Al, Ag, Co, Cr, Ir, Fe, Mo, Ti, Pd, Ru, Ta, Sc, Hf, Zr, V, Nb, Y, and rare earth metals.

3. A copper alloy sputter target as recited in claim 2 having a grain size of about 10 μm or less.

4. A copper alloy sputter target as recited in claim 3 wherein said grain size remains substantially the same after annealing at a temperature of from about 250° C.-470° C.

5. A copper alloying sputter target as recited in claim 2 wherein a surface of said target comprises a stable oxide layer.

6. A copper alloy sputter target comprising Cu and an alloying element, said alloying element being Al present in an amount of 0.001 wt %-10 wt %.

7. A copper alloy sputter target as recited in claim 6 wherein said Al is present in an amount of between about 0.01-1.0 wt %.

8. A copper alloy sputter target as recited in claim 6 wherein said grain size is about 10 μm or less throughout said target.

9. A copper alloy sputter target as recited in claim 6 further comprising a second alloying element or elements selected from the group consisting of Ag, Co, Cr, Ir, Fe, Mo, Ti, Pd, Ru, Ta, Sc, Hf, Zr, V, Nb, Y, and rare earth metals wherein said second alloying element or elements are present in a combined amount of between about 0.001-50 parts based upon one million parts of said sputter target.

10. A copper alloy sputter target as recited in claim 9 having a conductivity of between about 55.2-56.8% IACS.

11. A copper alloy sputter target as recited in claim 6 wherein said Cu has, by itself, a purity level of at least 5N.

12. A method of making a copper alloy sputter target comprising:
(a) providing a Cu material of at least about 99.9995 wt % purity;
(b) providing an alloying element or elements chosen from the group consisting of Al, Ag, Co, Cr, Ir, Fe, Mo, Ti, Pd, Ru, Ta, Sc, Hf, Zr, V, Nb, Y, and rare earths; and
(c) melting said Cu material (a) and said alloying element or elements (b) to form a molten copper alloy, and cooling and casting the molten alloy to form a copper alloy target comprising from about 0.001-10 wt % of said alloying element or elements (b).

13. Method as recited in claim 12 further comprising thermomechanically working and annealing said copper alloy to obtain a grain size of about 10 μm or less throughout said target.

14. Method as recited in claim 13 wherein said thermomechanical working comprises hot or cold rolling.

15. Method as recited in claim 14 wherein said thermomechanical working comprises hot or cold pressing.

16. Method as recited in claim 14 wherein said annealing is conducted at a temperature of between about 315° C. to 470° C.

17. Method as recited in claim 12 wherein said alloying element comprises Al.

18. Method as recited in claim 17 wherein said Al has a purity of at least 99.998 wt %, said Ti has a purity of at least 99.995 wt %, said Ir has a purity of at least 99.5 wt %, said Pd has a purity of at least 99.995 wt %, said Ti has a purity of least 99.5 wt %, and wherein said rare earth metals have a purity of at least 99 wt %.

19. Method as recited in claim 18 wherein said Al is present in an amount of between 0.1 and 1.0 wt %.

20. Method as recited in claim 19 wherein said Al is present in an amount of 0.5 wt %.
